(19) United States
(12) Patent Application Publication
(10) Pub. No.: US 2025/0379139 A1
(43) Pub. Date: Dec. 11, 2025

(54) HIGH VOLTAGE CAPACITOR ASSEMBLY

(71) Applicant: Allegro MicroSystems, LLC, Manchester, NH (US)

(72) Inventors: Thomas S. Chung, Merrimack, NH (US); Maxim Klebanov, Palm Coast, FL (US); Felix Palumbo, Buenos Aires (AR); Tzu-Tsai Yen, Hsinchu City (TW)

(73) Assignee: Allegro MicroSystems, LLC, Manchester, NH (US)

(21) Appl. No.: 18/734,480

(22) Filed: Jun. 5, 2024

(51) Int. Cl. H01L 23/522

(52) U.S. Cl. CPC H01L 23/5223; H10D 1/692

(57) ABSTRACT

The structure includes one or more capacitors formed in metal layers of a semiconductor die with the capacitors connected in series. The dielectric thickness of the capacitors is optimized to decrease parasitic capacitance and increase the breakdown voltage of the capacitor assembly.

### BACKGROUND

As is known in the art, signal isolators can be used to transfer information across a barrier used to separate two or more voltage domains for safety or functional isolation. For example, capacitive coupling can be used to transfer information across a barrier. Capacitors, however, have voltage ratings above which they may not perform properly or may fail. It is desirable in some applications to have capacitors with relatively high breakdown voltages formed as part of circuit board fabrication. However, fabrication technologies have certain limitations for forming capacitors having high breakdown voltages using conventional techniques.

The capacitive signal transmission in digital isolators uses capacitive coupling of signals. The capacitance consists of dielectrics between two metals. However, a significant parasitic capacitance exists from the capacitor bottom plate to the substrate. The parasitic capacitance may be even higher than that of the capacitance between plates due to the thinner dielectric layer between the bottom plate and the substrate.

### SUMMARY

Aspects of the present disclosure provide assemblies and methods for a structure having one or more capacitors formed in metal layers with the capacitors connected in series and having optimized dielectric thicknesses selected to decrease parasitic capacitance and increase the breakdown voltage of the capacitor assembly.

According to one aspect, an assembly may comprise a substrate having a major surface and alternating inter-metal dielectric (IMD) layers and metal layers above the major surface of the substrate. A first capacitor may have a first plate formed in a first one of the metal layers and a second plate formed in a second one of the metal layers. A second capacitor may have a third plate formed in a third one of the metal layers and a fourth plate formed in a fourth one of the metal layers. The first capacitor may be electrically coupled to the second capacitor.

The assembly may further include, alone or in combination, one or more of the following features. The first capacitor and the second capacitor may be electrically coupled in series. The second plate of the first capacitor may be electrically coupled to the third plate of the second capacitor. The second plate of the first capacitor and the third plate of the second capacitor may be configured to reduce a parasitic capacitance with the substrate. The first, second, third, and fourth plates may be configured to increase a breakdown voltage of the first capacitor and the second capacitor. The first and second plates may be vertically aligned with respect to the major surface of the substrate. The third and fourth plates may be vertically aligned with respect to the major surface of the substrate. The first plate may be configured for high voltage and the fourth plate may be configured for low voltage. The first and second capacitors may be configured to isolate a high voltage circuit from a low voltage circuit.

According to another aspect, a method of forming an assembly may include providing a substrate having a major surface and forming alternating IMD layers and metal layers above the major surface of the substrate. A first capacitor may have a first plate formed in a first one of the metal layers and a second plate formed in a second one of the metal layers. A second capacitor may have a third plate formed in a third one of the metal layers and a fourth plate formed in a fourth one of the metal layers. The first capacitor may be electrically coupled to the second capacitor.

The method may further include, alone or in combination, one or more of the following features. The first capacitor and the second capacitor may be electrically coupled in series. The second plate of the first capacitor may be electrically coupled to the third plate of the second capacitor. The second plate of the first capacitor and the third plate of the second capacitor may be configured to reduce a parasitic capacitance with the substrate. The first, second, third, and fourth plates may be configured to increase a breakdown voltage of the first capacitor and the second capacitor. The first and second plates may be vertically aligned with respect to the major surface of the substrate. The third and fourth plates may be vertically aligned with respect to the major surface of the substrate. The first plate may be configured for high voltage and the fourth plate may be configured for low voltage. The first and second capacitors may be configured to isolate a high voltage circuit from a low voltage circuit.

According to another aspect, a circuit may include a first semiconductor die comprising a receiver circuit and a second semiconductor die comprising a transmitter circuit. A third semiconductor die may comprise an isolator circuit structure coupling the receiver circuit and the transmitter circuit. The isolator circuit structure may include a substrate having a major surface and alternating inter-metal dielectric (IMD) layers and metal layers above the major surface of the substrate. A first capacitor may have a first plate formed in a first one of the metal layers and a second plate formed in a second one of the metal layers. A second capacitor may have a third plate formed in a third one of the metal layers and a fourth plate formed in a fourth one of the metal layers. The first capacitor may be electrically coupled to the second capacitor.

The circuit may further include, alone or in combination, one or more of the following features. The first capacitor and the second capacitor may be electrically coupled in series. The second plate of the first capacitor may be electrically coupled to the third plate of the second capacitor. The second plate of the first capacitor and the third plate of the second capacitor may be configured to reduce a parasitic capacitance with the substrate. The first, second, third, and fourth plates may be configured to increase a breakdown voltage of the first capacitor and the second capacitor. The first and second plates may be vertically aligned with respect to the major surface of the substrate. The third and fourth plates may be vertically aligned with respect to the major surface of the substrate. The first plate may be configured for high voltage and the fourth plate may be configured for low voltage. The first and second capacitors may be configured to isolate a high voltage circuit from a low voltage circuit.

### BRIEF DESCRIPTION OF THE DRAWINGS

The foregoing features of the disclosure, as well as the disclosure itself may be more fully understood from the following detailed description of the drawings. The drawings aid in explaining and understanding the disclosed technology. Since it is often impractical or impossible to illustrate and describe every possible embodiment, the provided figures depict one or more exemplary embodiments. Accordingly, the figures are not intended to limit the scope of the invention. Like numbers in the figures denote like elements.

FIG. 1 is a schematic representation of a signal isolator, according to aspects of the present disclosure;

FIG. 2A is a cross-sectional view of an example isolator circuit structure, according to aspects of the present disclosure;

FIG. 2B is a top view of the isolator circuit structure of FIG. 2A, according to aspects of the present disclosure;

FIG. 3 is a cross-sectional view of another example isolator circuit structure, according to aspects of the present disclosure; and

FIG. 4 is a cross-sectional view of another example isolator circuit structure, according to aspects of the present disclosure.

### DETAILED DESCRIPTION

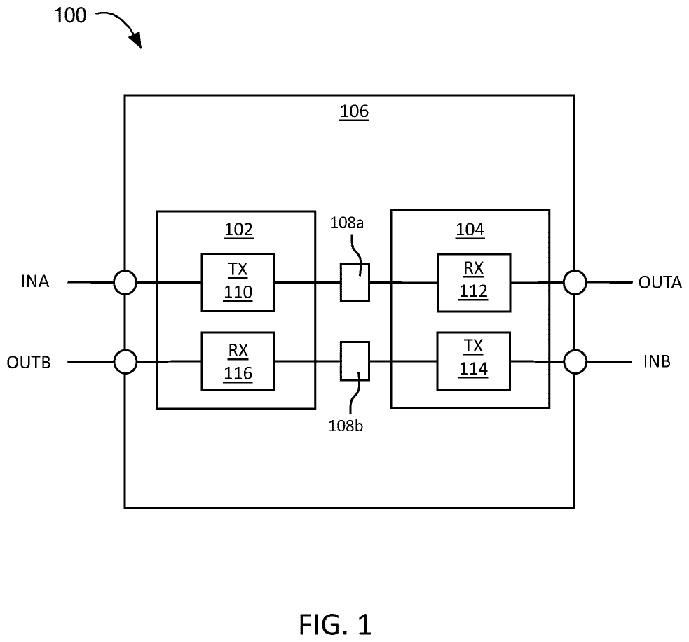

FIG. 1 shows an example of a signal isolator 100 including isolated first and second die 102, 104 that may form part of an integrated circuit (IC) package 106, according to aspects of the present disclosure. According to one aspect, the IC package 106 may include a first input signal INA connected to the first die 102 and a first output signal OUTA connected to the second die 104. The IC package 106 may further include a second input signal INB connected to the second die 104 and a second output signal OUTB to the first die 102.

According to one aspect, the first die 102 may include a first transmit module 110 and the second die 104 may include a first receive module 112 that provides a signal path from the first input signal INA to the first output signal OUTA across the first and second die 102, 104. A first isolation circuit 108a may connect the first transmit module 110 to the first receive module 112. The second die 104 may include a second transmit module 114 and the first die 102 may include a second receive module 116 that provides a signal path from the second input signal INB to the second output signal OUTB. A second isolation circuit 108b may connect the second transmit module 114 to the second receive module 116. While the signal isolator of FIG. 1 shows separate receiver and transmitter modules, it is understood that such module may be combined as a transmit/receive module.

The first and second isolation circuits 108a, 108b, may provide a galvanic isolation between the first die 102 and the second die 104 allowing the respective die to be externally connected to significantly different voltage domains. For example, the first voltage domain may be typical digital circuit voltage levels and the second voltage domain can be a higher level voltage domain, such as 1500V or higher. It is understood that the potential difference between grounds of the first and second voltage domain can range from zero to hundreds or thousands of volts. According to one aspect, the first and second die 102, 104 may have separate voltage supply signals and separate ground connections.

According to one aspect, the first and second isolation circuits 108a, 108b may be formed over discrete semiconductor die, separate from the first die 102 and the second die 104. As described herein, providing isolation circuits 108a, 108b may decrease or avoid potential parasitic capacitance between the upper layers of the die and the substrate of the die. These isolation circuits can be discrete circuits from dies 102 or 104. Alternatively, the isolation circuits 108a, 108b can be integrated with dies 102 or 104.

It is understood that any practical number of transmit, receive, and transmit/receive modules can be formed on the first and/or second die to meet the needs of a particular application. It is further understood that transmit, receive, and transmit/receive modules can comprise the same or different components. In addition, according to some aspects, bi-directional communication is provided across the isolation circuits 108a, 108b. Further, circuity in the first die 102 and/or the second die 104 can be provided to process signals, perform routing of signals, and the like. According to one aspect, sensing elements may be formed in, on, or about the first and/or second die.

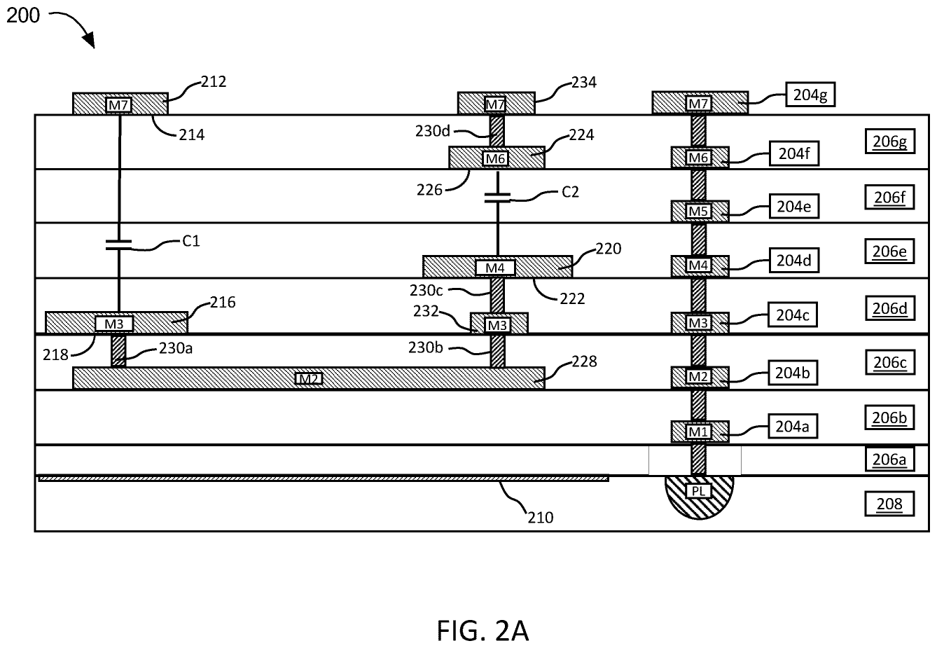

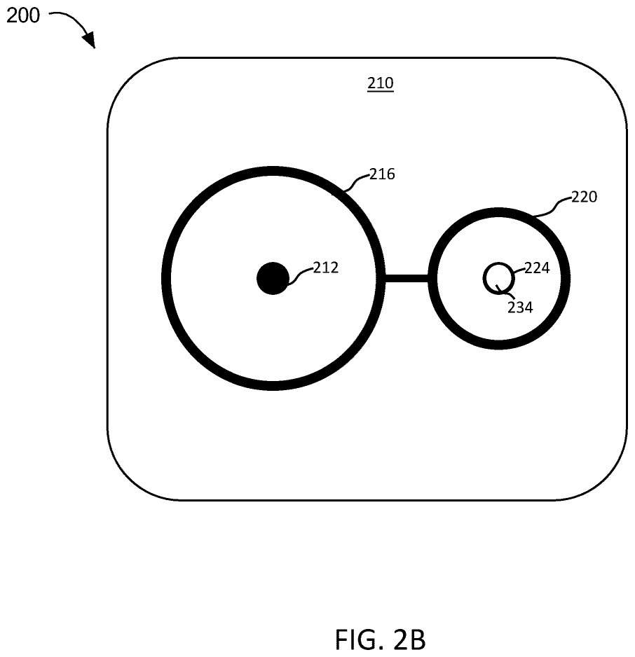

FIG. 2A is a cross-section and FIG. 2B is a top view of an isolator circuit structure 200 having a first capacitor C1 and a second capacitor C2 formed by metal regions and interconnects between metal layers. The structure 200 may include a series of metal layers 204a-g and inter-metal dielectric (IMD) layers 206a-g between metal layers. Interconnects may comprise SiO₂ and/or silicon nitride, for example, and may be formed using back-end-of-the-line (BEOL) processing, or the like. The metal layers 204 and IMD layers 206 may be formed on a substrate 208, such as a silicon substrate. According to one aspect, a shallow trench isolation (STI) layer 210 can be formed on the substrate 208. The STI layer 210 may prevent current leakage between adjacent device components. The STI layer 210 may be formed prior to the circuit formation.

According to one aspect, the first capacitor C1 may include a first plate 212 formed by a first metal region 214 in metal layer 204g and a second plate 216 formed by a second metal region 218 in metal layer 204c. In the illustrated embodiment, the first and second plates 212, 216 are spaced apart by about 4 to 20 μm for example. The second capacitor C2, according to one aspect, may include a third plate 220 formed by a third metal region 222 in metal layer 204d and a fourth plate 224 formed by a fourth metal region 226 in metal layer 204f. In the illustrated embodiment, the third and fourth plates 220, 224 are spaced apart by about 2 to 10 μm for example. According to one aspect, the first plate 212 may have a center aligned with a center of the second plate 216 with respect to the major surface of the substrate 208. Similarly, the third plate 220 may have a center aligned with a center of the fourth plate 224.

The first capacitor C1 and the second capacitor C2 may be connected in series, according to one aspect. The second plate 216 (capacitor C1) may be coupled to an elongate metal region 228 formed in metal layer 204b extending laterally to be underneath at least a portion of the second plate 216 (capacitor C1) and at least a portion of the third plate 220 (capacitor C2). The elongate metal region 228 may be coupled to the second plate 216 (capacitor C1) by one or more interconnects, such as interconnect 230a in IMD layer 206c. The third plate 220 (capacitor C2) may be coupled to the elongate metal region 228 by metal region 232 and a series of interconnects 230b, 230c in IMD layers 206c, 206d, respectively.

According to one aspect, the first plate 212 may be coupled to a high voltage terminal and the fourth plate 224 may be coupled to a low voltage terminal. In the illustrated embodiment, a metal region 234 in metal layer 204g and an interconnect 230d in IMD layer 206g may form an electrical connection from the fourth plate 224 (capacitor C2) the top surface of the structure 200. This may enable a low voltage connection to the fourth plate 224 from the top of the structure 200. It is understood that metal regions 228, 232, interconnects 230a-c and second plate 216 and third plate 220 may contribute to the structure and impedance characteristics of the capacitors C1, C2.

While the illustrative example shown in FIG. 2A depicts the first capacitor C1 in the M3 and M7 metal layers, and the second capacitor C2 in the M4 and M6 layers, it will be understood from the present disclosure that the capacitors C1 and C2 may be configured according to the size of the plates, the metal layers in which the plates are formed (e.g., layers 204), and the thickness of the dielectric (e.g., the number of IMD layers 206) between the plates to increase the breakdown voltage of the structure as well as decrease the parasitic capacitance between the bottom plates and the substrate. In the example of FIG. 2A, the dielectric thickness of the first capacitor C1 may include IMD layers 206d through 206g, while the thickness of the second capacitor C2 includes IMD layers 206e through 206f. According to one aspect, the dielectric thickness of the series-connected capacitors, C1 and C2, may be considered the sum of the thickness of each individual capacitor. According to one aspect, the selection and implementation of the dielectric thickness of the capacitors C1 and C2 may be optimized according to the intended application and the balance of higher breakdown voltage with the potential parasitic capacitance between the capacitors themselves and the substrate.

For example, if both capacitors C1 and C2 were implemented with the same dielectric thickness from IMD layer 206d to IMD layer 206g, the circuit may achieve a maximum breakdown voltage, however, the parasitic capacitance may be unacceptably high. In contrast, if capacitor C2 is formed, as shown in FIG. 2A (with a dielectric thickness from IMD layer 206e to IMD layer 206g), the breakdown voltage may be reduced, however, the parasitic capacitance is also reduced. Accordingly, the selection and fabrication of the size of the plates and the selection of metal layers to form the plates allows for the customization and optimization of the capacitive isolation provided by the isolator circuit structure 200.

According to one aspect, the isolator circuit structure 200 may be implemented as a discrete component, chip, or die between a transmitter and a receiver operating in different voltage domains. For example, isolation circuits 108a, 108b of FIG. 1 may be or include the isolator circuit structure 200. According to one aspect, providing the isolator circuit structure 200 as a discrete component, separate from the transmitter/receiver modules or circuits, may decrease or avoid parasitic capacitance caused by the proximity of those circuits to the substrate when integrated into a single chip. In this case, the isolator circuit structure 200 can be separate from the substrate and no parasitic capacitance may occur. In such a manner, the substrate can be considered floating

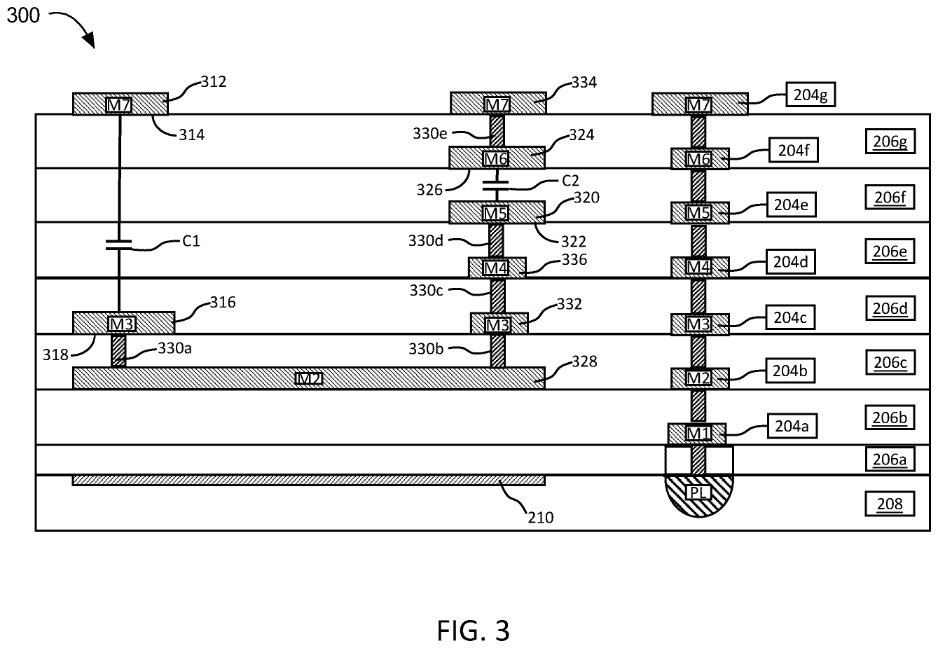

FIG. 3 is a cross-section of another example isolator circuit structure 300 having a first capacitor C1 and a second capacitor C2 formed by metal regions and interconnects between metal layers. The structure 300 may be similar to the isolator circuit 200 (FIG. 2A) wherein like reference numbers indicate like elements.

According to one aspect, the first capacitor C1 may include a first plate 312 formed by a first metal region 314 in metal layer 204g and a second plate 316 is formed by a second metal region 318 in metal layer 204c. In the illustrated embodiment, the first and second plates 312, 316 are spaced apart by about 4 to 20 μm for example. The second capacitor C2, according to one aspect, may include a third plate 320 formed by a third metal region 322 in metal layer 204e and a fourth plate 324 is formed by a fourth metal region 326 in metal layer 204f. In the illustrated embodiment, the third and fourth plates 322, 326 are spaced apart by about 1 to 5 μm for example.

The first capacitor C1 and the second capacitor C2 may be connected in series, according to one aspect. The second plate 316 (capacitor C1) may be coupled to an elongate metal region 328 formed in metal layer 204b extending laterally to be underneath at least a portion of the second plate 316 (capacitor C1) and at least a portion of the third plate 320 (capacitor C2). The elongate metal region 328 may be coupled to the second plate 316 (capacitor C1) by one or more interconnects, such as interconnect 330a in IMD layer 206c. The third plate 320 (capacitor C2) may be coupled to the elongate metal region 328 by series of metal regions 332, 336 and a series of via interconnects 330b, 330c, 330d in IMD layers 206c, 206d, 206e respectively.

According to one aspect, the first plate 312 may be coupled to a high voltage terminal and the fourth plate 324 may be coupled to a low voltage terminal. In the illustrated embodiment, a metal region 334 in metal layer 204g and an interconnect 330e in IMD layer 206g form an electrical connection from the fourth plate 324 (capacitor C2) the top surface of the structure 300. This may enable a low voltage connection to the fourth plate 324 from the top of the structure 300. It is understood that metal regions 328, 332, 336 interconnects 330a-d and second plate 316 and third plate 320 may contribute to the structure and impedance characteristics of the capacitors C1, C2.

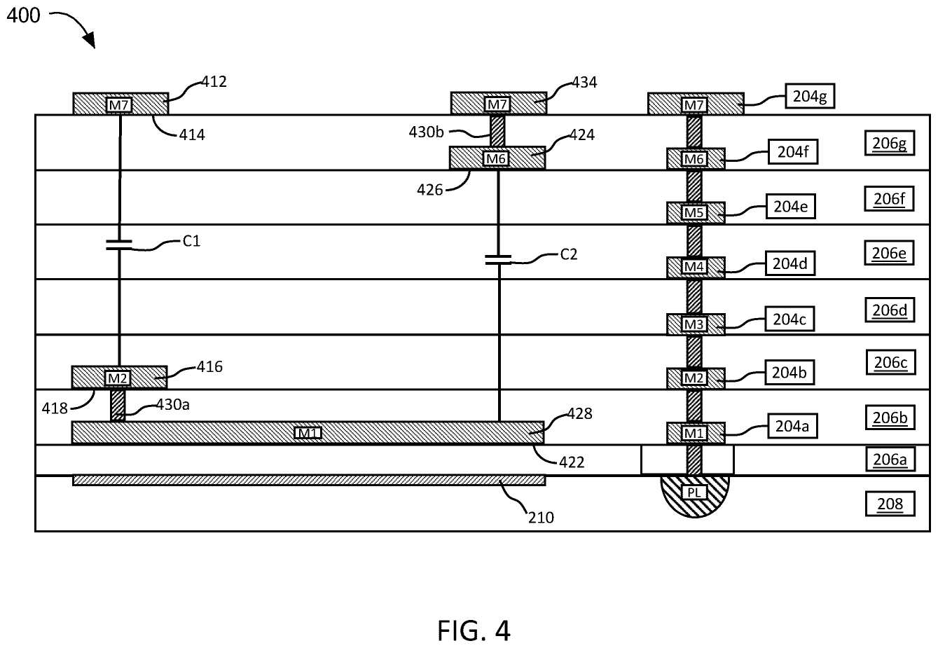

FIG. 4 is a cross-section of another example isolator circuit structure 400 having a first capacitor C1 and a second capacitor C2 formed by metal regions and interconnects between metal layers. The structure 400 may be similar to the isolator circuit 200 (FIG. 2A) wherein like reference numbers indicate like elements.

According to one aspect, the first capacitor C1 may include a first plate 412 formed by a first metal region 414 in metal layer 204g and a second plate 416 is formed by a second metal region 418 in metal layer 204b. In the illustrated embodiment, the first and second plates 412, 416 are spaced apart by about 4 to 20 μm for example. The second capacitor C2, according to one aspect, may include a third plate 428 formed by a third metal region 422 in metal layer 204a and a fourth plate 424 is formed by a fourth metal region 426 in metal layer 204f. In the illustrated embodiment, the third and fourth plates 428, 424 are spaced apart by about 4 to 20 μm for example.

The first capacitor C1 and the second capacitor C2 may be connected in series, according to one aspect. The third plate 428 may be or form an elongated metal region extending laterally to be underneath at least a portion of the second plate 416 (capacitor C1). The third plate 428 may be coupled to the second plate 416 (capacitor C1) by one or more interconnects, such as interconnect 430a in IMD layer 206b.

According to one aspect, the first plate 412 may be coupled to a high voltage terminal and the fourth plate 424 may be coupled to a low voltage terminal. In the illustrated embodiment, a metal region 434 in metal layer 204g and an interconnect 430b in IMD layer 206g form an electrical connection from the fourth plate 424 (capacitor C2) the top surface of the structure 400. This may enable a low voltage connection to the fourth plate 424 from the top of the structure 400. It is understood that interconnect 430a, second plate 416 and third plate 428 may contribute to the structure and impedance characteristics of the capacitors C1, C2.

It is understood that a wide range of lateral and vertical distances between components of the structure can vary to meet the needs of a particular application. It is further understood that any practical number of layers can be used in the structure and that one or more capacitors can be formed in any practical number of layers.

It is understood that example capacitor embodiments are applicable to a wide range of circuits and applications, such as isolated gate drivers, motor drivers, and power circuits in general in which space and cost and capacitor operating voltage are considerations.

It is further understood that while example capacitor embodiments may be shown and described in circular shapes, it is understood that any suitable geometry, such a square, rectangular, etc., can be used to meet the needs of a particular application.

In addition, it is understood that any suitable dielectric materials can be used to form example capacitor configuration. In some embodiments, dielectric materials, such as Tetraethyl Orthosilicate (TEOS) oxide and High density plasma (HDP) CVD oxidecan be used.

The detailed description set forth above, in connection with the appended drawings, is intended as a description of various configurations and is not intended to represent the only configurations in which the concepts described herein may be practiced. The detailed description includes specific details for providing a thorough understanding of the various concepts. It will be apparent to those skilled in the art, however, that these concepts may be practiced without these specific details. In some instances, well-known structures and components are shown in block diagram form in order to avoid obscuring such concepts.

(The following statements may not related to the topic of the claims)

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it may affect such feature, structure, or characteristic in other embodiments whether explicitly described or not.

Use of ordinal terms such as “first,” “second,” “third,” etc., in the claims to modify a claim element does not by itself connote any priority, precedence, or order of one claim element over another, or a temporal order in which acts of a method are performed, but are used merely as labels to distinguish one claim element having a certain name from another element having a same name (but for use of the ordinal term) to distinguish the claim elements.

In the foregoing detailed description, various features of embodiments are grouped together in one or more individual embodiments for the purpose of streamlining the disclosure. This method of disclosure is not to be interpreted as reflecting an intention that the claims require more features than are expressly recited therein. Rather, inventive aspects may lie in less than all features of each disclosed embodiment.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

Having described implementations which serve to illustrate various concepts, structures, and techniques which are the subject of this disclosure, it will now become apparent to those of ordinary skill in the art that other implementations incorporating these concepts, structures, and techniques may be used. Accordingly, it is submitted that that scope of the patent should not be limited to the described implementations but rather should be limited only by the spirit and scope of the following claims.

What is claimed is:

1. An assembly comprising:
a substrate having a major surface;
alternating inter-metal dielectric (IMD) layers and metal layers above the major surface of the substrate;
a first capacitor having a first plate formed in a first one of the metal layers and a second plate formed in a second one of the metal layers; and
a second capacitor having a third plate formed in a third one of the metal layers and a fourth plate formed in a fourth one of the metal layers;
wherein the first capacitor is electrically coupled to the second capacitor.

2. The assembly of claim 1 wherein the first capacitor and the second capacitor are electrically coupled in series.

3. The assembly of claim 2 wherein the second plate of the first capacitor is electrically coupled to the third plate of the second capacitor.

4. The assembly of claim 1 wherein the second plate of the first capacitor and the third plate of the second capacitor are configured to reduce a parasitic capacitance with the substrate.

5. The assembly of claim 4 wherein the first, second, third, and fourth plates are configured to increase a breakdown voltage of the first capacitor and the second capacitor.

6. The assembly of claim 1 wherein the first and second plates are vertically aligned with respect to the major surface of the substrate.

7. The assembly of claim 1 wherein the third and fourth plates are vertically aligned with respect to the major surface of the substrate.

8. The assembly of claim 1 wherein the first plate is configured for high voltage and the fourth plate is configured for low voltage.

9. The assembly of claim 1 wherein the first and second capacitors are configured to isolate a high voltage circuit from a low voltage circuit.

10. A method of forming an assembly, the method comprising:
providing a substrate having a major surface;
forming alternating inter-metal dielectric (IMD) layers and metal layers above the major surface of the substrate;
forming a first capacitor having a first plate formed in a first one of the metal layers and a second plate formed in a second one of the metal layers;
forming a second capacitor having a third plate formed in a third one of the metal layers and a fourth plate formed in a fourth one of the metal layers; and
electrically coupling the first capacitor to the second capacitor.

11. The method of claim 10 wherein the first capacitor and the second capacitor are electrically coupled in series.

12. The method of claim 10 wherein the second plate of the first capacitor is electrically coupled to the third plate of the second capacitor.

13. The method of claim 10 wherein the second plate of the first capacitor and the fourth plate of the second capacitor are configured to reduce a parasitic capacitance with the substrate.

14. The method of claim 13 wherein the first, second, third and fourth plates are configured to increase a breakdown voltage of the first capacitor and the second capacitor.

15. The method of claim 10 wherein the first and second plates are vertically aligned with respect to the major surface of the substrate.

16. The method of claim 10 wherein the third and fourth plates are vertically aligned with respect to the major surface of the substrate.

17. The method of claim 10 wherein the first plate is configured for high voltage and the fourth plate is configured for low voltage.

18. The method of claim 10 wherein the first and second capacitors are configured to isolate a high voltage circuit from a low voltage circuit.

19. An integrated circuit comprising:
a first semiconductor die comprising a receiver circuit;
a second semiconductor die comprising a transmitter circuit; and
a third semiconductor die comprising an isolator circuit structure, wherein the isolator circuit structure includes:
a substrate having a major surface;
alternating inter-metal dielectric (IMD) layers and metal layers above the major surface of the substrate;
a first capacitor having a first plate formed in a first one of the metal layers and a second plate formed in a second one of the metal layers; and
a second capacitor having a third plate formed in a third one of the metal layers and a fourth plate formed in a fourth one of the metal layers;
wherein the first capacitor is electrically coupled to the second capacitor.

20. The circuit of claim 19 wherein the first capacitor and the second capacitor are electrically coupled in series.

21. The circuit of claim 19 wherein the second plate of the first capacitor is electrically coupled to the third plate of the second capacitor.

22. The circuit of claim 19 wherein the second plate of the first capacitor and the fourth plate of the second capacitor are configured to reduce a parasitic capacitance with the substrate.

23. The circuit of claim 22 wherein the first, second, third and fourth plates are configured to increase a breakdown voltage of the first capacitor and the second capacitor.

24. The circuit of claim 19 wherein the first and second plates are vertically aligned with respect to the major surface of the substrate.

25. The circuit of claim 19 wherein the third and fourth plates are vertically aligned with respect to the major surface of the substrate.

26. The circuit of claim 19 wherein the first plate is configured for high voltage and the fourth plate is configured for low voltage.

27. The circuit of claim 19 wherein the first and second capacitors are configured to isolate a high voltage circuit from a low voltage circuit.
